(19) United States
(12) Patent Application Publication
(10) Pub. No.: US 2013/0162123 A1
(43) Pub. Date: Jun. 27, 2013

(54) ELECTRONIC DEVICE ENCLOSURE

(71) Applicant: FU-MING LIU, Shenzhen City (CN)

(72) Inventor: FU-MING LIU, Shenzhen City (CN)

(21) Appl. No.: 13/653,450

(22) Filed: Oct. 17, 2012

(30) Foreign Application Priority Data
Dec. 26, 2011 (CN) 201110441221.9

(51) Int. Cl. H05K 5/03

(52) U.S. Cl. 312/223.1

(57) ABSTRACT

An electronic device enclosure includes a side plate, a fixing member, and a handle pivotally mounted on the fixing member. The side plate defines a depression. The fixing member is mounted in the depression. The fixing member includes a base plate and two locking members mounted on the base plate. The base plate includes two pairs of locking portions. A locking slot is defined in each of the two pairs of locking portions. The two locking members are slid in the two pairs of locking portions along the locking slots. The handle includes two mounting portions extending toward each other from the handle. The two mounting portions extend in two opposite directions and are engaged with the two locking members.

### BACKGROUND

1. Technical Field

The present disclosure relates to an electronic device enclosure with a handle.

2. Description of Related Art

Electronic devices such as personal computers and servers sometimes need to be moved in use. Some of electronic devices have handles extending from cases of these electronic devices to facilitate moving. The handles often extend away from the electronic device, the handles occupy a large amount space of the electronic device.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure, the electronic device enclosure comprising a fixing member.

FIG. 2 is an enlarged view of the fixing member of FIG. 1.

FIG. 3 is an assembled view of the electronic device enclosure of FIG. 1.

FIG. 4 is similar to FIG. 3, but shows the assembled view of the electronic device enclosure in another position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

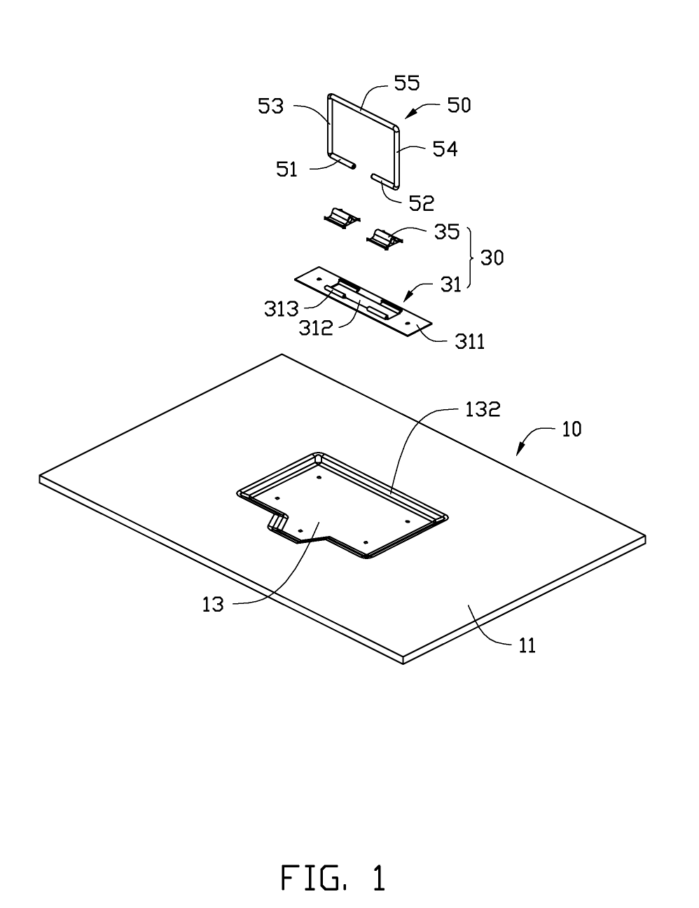

FIG. 1 illustrates an electronic device enclosure in accordance with one embodiment. The electronic device enclosure includes a side plate 10, a fixing member 30 mounted on the side plate 10, and a handle 50 pivotally mounted on the fixing member 30.

The side plate 10 includes an outer surface 11 and a depression 13 defined in the outer surface 11. A plurality of diagonal fringe portions 132 are located between side edges of the depression 13 and the outer surface 11. In one embodiment, the depression 13 is approximately rectangular-shaped. The fringe portions 132 may be arc-shaped, for example. In another embodiment, the depression 13 can be T-shaped, circular, or oval-shaped, etc.

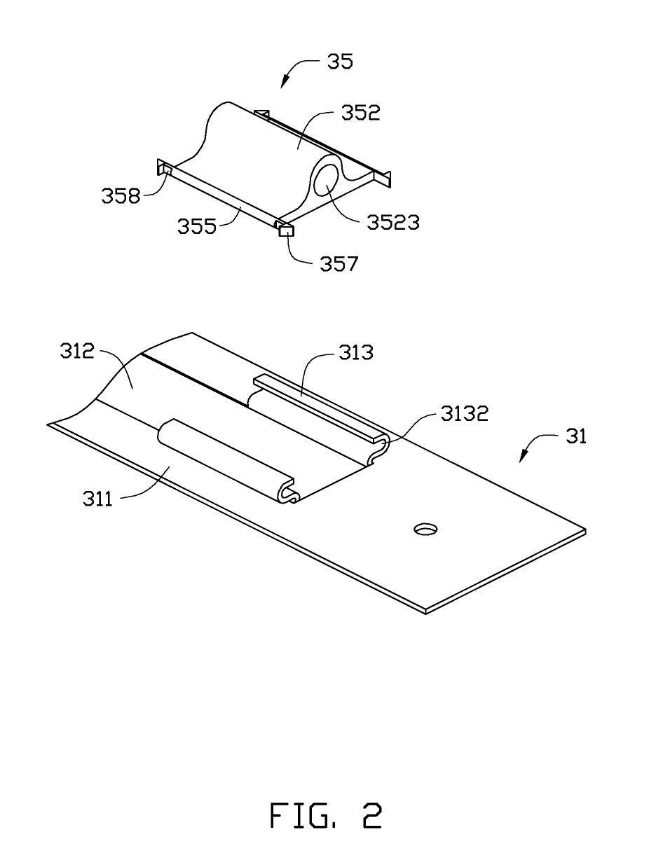

FIG. 2 illustrates the fixing member 30 in accordance with one embodiment. The fixing member 30 includes a base plate 31 and two locking members 35 mounted on the base plate 31. The base plate 31 includes a body portion 311 and two pairs of locking portions 313 extending upwardly from the base plate 31. A rectangular-shaped opening 312 is defined in the body portion 311. Each of the two pairs of locking portions 313 are located on two sides of the opening 312. The body portion 311 is bar-shaped to be located on one side of the depression 13. A locking slot 3132 is defined in each of the two pairs of locking portions 313. In one embodiment, a thickness of the fixing member 30 is less than or equal to a depth of the depression 13.

Each of the two locking members 35 includes a pivoting portion 352 and two sliding portions 355 horizontally located on two sides of the pivoting portion 352. In this embodiment, the pivoting portion 352 is a hollow column An outer surface of the pivoting portion 352 is arc-shaped. A pivoting hole 3523 is defined in each of the pivoting portion 352. Two elastic hooks 357 are located on two distal ends of each of the two sliding portions 355. Two connecting portions 358 are located on each of the two sliding portions 355 and connected to the two elastic hooks 357. In one embodiment, a thickness of the connecting portions 358 is less than a thickness of the sliding portions 355.

The handle 50 includes two mounting portions 51 and 52, two extending portions 53 and 54 connected to the two mounting portions 51 and 52 respectively, and an operation portion 55 connected to the two extending portions 53 and 54. The two mounting portions 51 and 52 extend from the handle 50 toward each other. The two extending portions 53 and 54 and the operation portion 55 cooperatively form a rectangular-shaped operation space.

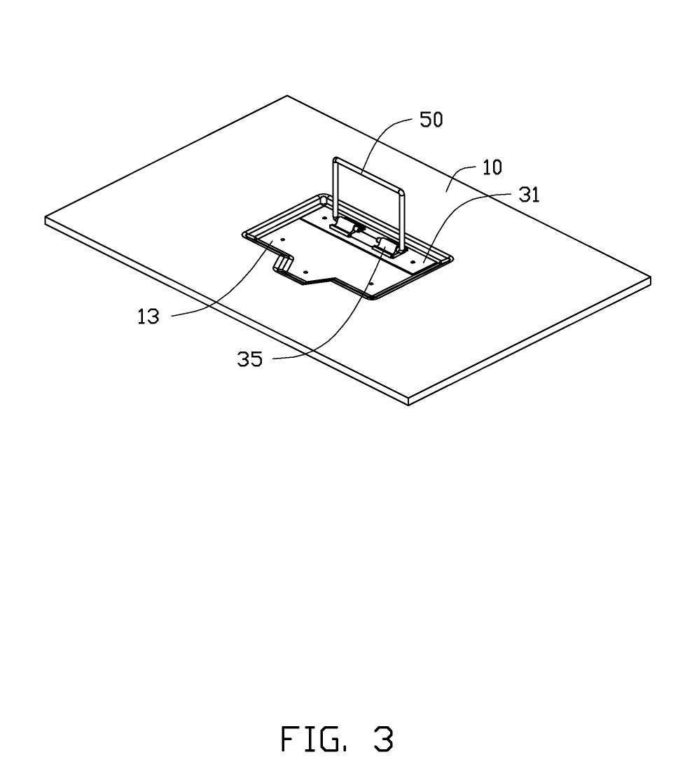

Referring to FIG. 3, in assembly, the fixing member 30 is riveted in the depression 13. The two locking members 35 are slid in the two pairs of locking portions 313 along the locking slots 3132. The elastic hooks 357 on each of the two locking members 35 abut two sides of the locking slot 3132. The two locking members 35 are located between the two pairs of locking portions 313. The two mounting portions 51 and 52 of the handle 50 are extended in the pivoting holes 3523 on the two locking members 35 along two opposite directions.

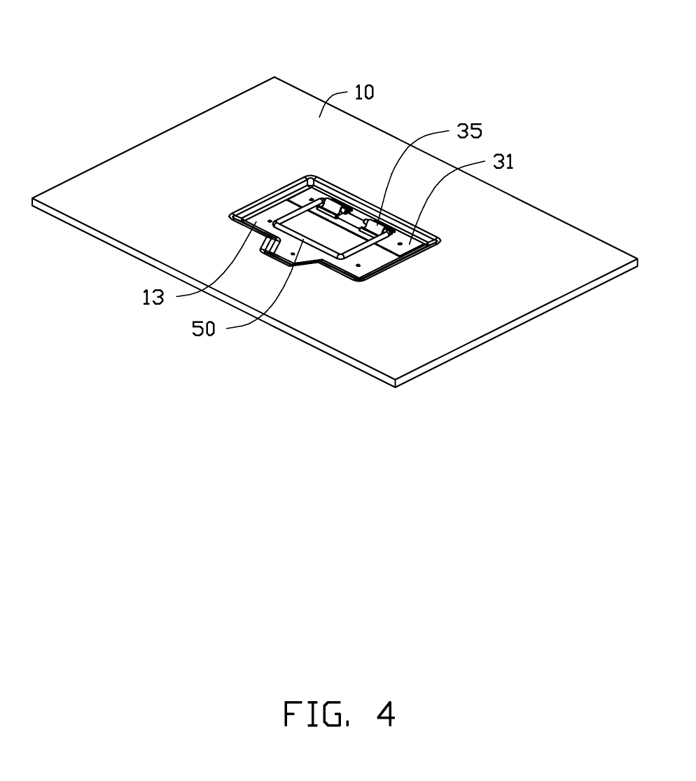

Referring to FIG. 4, in use, the operation portion 55 is pivotally rotated around the two locking members 35 to an angle relative to the outer surface 11 of the side plate 10. The electronic device enclosure is then moved to a desired place by lifting the operation portion 55. When the electronic device enclosure is moved to the desired place, the operation portion 55 is pivotally rotated around the two locking members 35 to be received in the depression 13 again.

In another embodiment, the fixing member 30 can also be mounted in the in the depression 13 by fasteners, such as screws.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a side plate defining a depression therein;
a fixing member mounted in the depression; the fixing member comprises a base plate and two locking members each mounted on the base plate; the base plate comprises two pairs of locking portions; a locking slot is defined in each locking portion of the two pairs of locking portions; each of the two locking members is slid into each pair of the two pairs of locking portions along the locking slot; and
a handle pivotally mounted on the fixing member; the handle comprises two mounting portions extending toward each other from the handle; and the two mounting portions extend in two opposite directions and each of the two mounting portions is engaged with each of the two locking members.

2. The electronic device enclosure of claim 1, wherein each of the two locking members comprises a pivoting portion and two sliding portions horizontally located on two sides of the pivoting portion.

3. The electronic device enclosure of claim 2, wherein the pivoting portion is column shaped and hollow in the middle; and an outer surface of the pivoting portion is arc-shaped.

4. The electronic device enclosure of claim 2, wherein a pivoting hole is defined in the pivoting portion; and each of the two mounting portions is inserted into the pivoting hole of each of the two locking members along opposite directions.

5. The electronic device enclosure of claim 2, wherein two elastically hooks are located on two distal ends of each of the two sliding portions.

6. The electronic device enclosure of claim 5, wherein two connecting portions are located on each of the two sliding portions and each of the two connecting portions is connected to each of the two elastically hooks.

7. The electronic device enclosure of claim 6, wherein a thickness of the connecting portions is less than a thickness of the sliding portions.

8. The electronic device enclosure of claim 1, wherein the base plate further comprises a body portion defining a rectangular-shaped opening; and each pair of the locking portions is located on each side of the opening.

9. The electronic device enclosure of claim 1, wherein a plurality of diagonal fringe portions are located around side edges of the depression; the depression is approximately rectangular-shaped; and a thickness of the fixing member is less than or equal to a depth of the depression portion.

10. The electronic device enclosure of claim 1, wherein the handle further comprises two extending portions, each of the two extending portions being connected to each of the two mounting portions, and an operation portion connected to each of the two extending portions; and the two extending portions and the operation portion cooperatively form a rectangular-shape operation space.

11. An electronic device enclosure comprising:
a side plate;
a fixing member mounted on the side plate; the fixing member comprises a base plate and two locking members each mounted on the base plate; the base plate comprises two pairs of locking portions; a locking slot is defined in each locking portion of the two pairs of locking portions; each of the two locking members is slid into each pair of the two pairs of locking portions along the locking slots; and
a handle pivotally mounted on the fixing member; the handle comprises two mounting portions, two extending portions, each of the two extending portions being connected to each of the two mounting portions, and an operation portion connected to each of the two extending portions; the two mounting portions extends toward each other from the handle; and the two mounting portions extend in two opposite directions and each of the two mounting portions is engaged with each of the two locking members.

12. The electronic device enclosure of claim 11, wherein a depression is defined in the side plate; the fixing member is mounted in the depression; and the depression is approximately rectangular-shaped.

13. The electronic device enclosure of claim 12, wherein a plurality of diagonal fringe portions are located around side edges of the depression.

14. The electronic device enclosure of claim 11, wherein each of the two locking members comprises a pivoting portion and two sliding portions horizontally located on two sides of the pivoting portion.

15. The electronic device enclosure of claim 14, wherein the pivoting portion is column shaped and hollow in the middle; and an outer surface of the pivoting portion is arc-shaped.

16. The electronic device enclosure of claim 14, wherein a pivoting hole is defined in the pivoting portion; and each of the two mounting portions is inserted into the pivoting holes of each of the two locking members along opposite directions.

17. The electronic device enclosure of claim 14, wherein two elastically hooks are located on two distal ends of each of the two sliding portions.

18. The electronic device enclosure of claim 17, wherein two connecting portions are located on each of the two sliding portions and each of the two connecting portions is connected to each of the two elastically hooks.

19. The electronic device enclosure of claim 18, wherein a thickness of the connecting portions is less than a thickness of the sliding portions.

20. The electronic device enclosure of claim 11, wherein the base plate further comprises a body portion defining a rectangular-shaped opening; and each pair of the locking portions are located on each side of the opening.
